(19) United States
(12) Patent Application Publication
(10) Pub. No.: US 2025/0364219 A1
(43) Pub. Date: Nov. 27, 2025

(54) LOW GWP PLASMA ETCHING PROCESS USING C6F12

(71) Applicant: L'Air Liquide, Société Anonyme pour I'Etude et I'Exploition des Procédés Georges Claude, Paris (FR)

(72) Inventors: Nathan STAFFORD, Bear, DE (US); Phong NGUYEN, Newark, DE (US)

(21) Appl. No.: 18/671,364

(22) Filed: May 22, 2024

(51) Int. Cl. H01J 37/32

(52) U.S. Cl. CPC H01J 37/3244; H01J 37/32724; H01J 2237/3341

(57) ABSTRACT

An etching method for forming an aperture in a substrate comprises exposing the substrate to an etching gas containing a non-cyclic C₆F₁₂; converting the etching gas to a plasma; allowing an etching reaction to proceed between the plasma and one or more silicon-containing films containing in the substrate so that the one or more silicon-containing films are selectively etched versus a patterned mask layer deposited on top of the one or more silicon-containing films to form the aperture therein and volatile by-products; and removing the volatile by-products. CO_{2eq} emissions of the volatile by-products are reduced compared to an etching process using etching gases with GWP₁₀₀>30.

### TECHNICAL FIELD

The present invention relates to silicon material plasma etching, patterning process with low global warming potential (GWP) etching gas and low GWP emissions utilizing C₆F₁₂ and other etch gas co-reactants, in particular, utilizing C₆F₁₂ and other etch gas co-reactants in etching conditions.

### BACKGROUND

Traditionally, silicon material plasma etching is used in the patterning process to manufacturer semiconductor chip devices and is performed using fluorine containing gases owing to the primary byproduct formed being SiF₄. For pattern etching of silicon materials, such as SiO₂, often a carbon containing fluorine molecule is used owing to the carbon and fluorine containing polymer formed to protect the sidewall of the etched structure. The addition of ion bombardment in the etching process accelerates the chemical reaction in the vertical direction so that vertical sidewalls are formed along the edges of the masked features at right angles to the substrate (Manos and Flamm, Plasma Etching An Introduction, Academic Press, Inc. 1989). However, most of the fluorocarbon etching gases have a high global warming potential (GWP) due to the C—F bond absorption within in the IR spectral range of 1000-1500 cm⁻¹ which overlaps with the output radiation spectral range of the Earth. This strong absorption along with the strong bond strength of the C—F bond results in the fluorocarbon molecules having a high heat trapping impact over long periods of time and thus resulting in global warming. C₄F₆ is a common silicon material etchant used in a variety of patterning process to manufacture semiconductor devices. However, it has a high GWP, 9,540 times the global warming impact as compared to CO₂.

C₆F₁₂ is a known etchant from the prior art references listed below. It has been disclosed in formula for applications including etching SiO₂, SiN and Si. It has been known C₆F₁₂ has cyclic and noncyclic isomers. It has been known C₆F₁₂ may be mixed with other gases including fluorocarbons, hydrofluorocarbons, inert gas and oxygen among other gases (with limitations described below). It has been known noncyclic C₆F₁₂ is a lower GWP gas as compared to the cyclic C₆F₁₂ isomer. There is a need for low GWP alternative etching gases to replace the high GWP fluorocarbon etching gases.

JP2012043869 discloses etching gas C₆F₁₂. C₆F₁₂ is the isomer (C₆F₁₂ (A), CAS No.: 2070-70-4) and C₆F₁₂ (B), CAS NO.: 1584-03-8). The etching rate and selectivity of the two isomers of C₆F₁₂ vs C₄F₈ are disclosed. Note here, JP2012043869 only add a small amount of C₆F₁₂ and only show it mixed with C₅F₈. They do not etch with C₆F₁₂ only in the example and they do not talk about SiN etching. When mixing C₆F₁₂+C₅F₈, a higher etching rate than that of C₄F₈+C₅F₈ is observed but only 1.2 times.

U.S. Pat. No. 7,022,616 discloses etching of Si with SiO₂ as a mask. Various types of gases below may be utilized. Any one of these gases may be used alone, or a plurality of gases among these gases may be used in mixture. That is, an unsaturated carbon fluoride compound gas having one or more double bonds or triple bonds expressed by CₓF_{y} (y<2x+2) such as: C₂F₄, C₂F₂, C₃F₆, C₃F₄, C₄F₈, C₄F₆, C₄F₄, C₄F₂, C₅F₁₀, C₅F₈, C₅F₆, C₅F₄, C₆F₁₂, C₆F₁₀, C₆F₈, C₆F₆, or the like.

JP3253215 discloses an etching method and etching apparatus for etching SiO₂ selective to SiN. Examples of the halogenated carbon-based gas include CₓF_{y}-based gas having a relationship of y≤2x+2. For example, C₄F₆ may be used. Those satisfying the relational expression of y=2x+2 include saturated fluorocarbon compound gases such as CF₄, C₃F₈, and C₅F₁₂, C₇F₁₆, C₉F₂₀, C₂F₆, C₄F₁

Gases such as 0, C₆F₁₄, C₈F₁₈, and C₁₀F₂₂ and satisfying the relational expression of y<2x+2 include those having at least one double bond or triple bond that is an unsaturated fluorocarbon compound gas, for example, C₂F₄, C₂F₂, C₆F₇, C₆F₄, C₄F₈, C₄F₈, C₄F₄, C₄F₂, C₅F₁₀, C₅F₈, C₅F₆, C₅F₄, C₆F₁₂, C₆F₁₀, C₆F₈, C₆F₆ and the like.

U.S. Pat. No. 7,153,779 discloses a method to eliminate striations and surface roughness caused by dry etch using the fluorocarbon gas component of the etch gas that may comprise a single organic fluorocarbon gas used alone, or a mixture of two or more organic fluorocarbon gases. The organic fluorocarbon gas may comprise one or more 1-2 carbon fluorocarbon gases having the general formula CₓH_{y}F_{z} wherein x is 1 to 2, y is 0 to 3, and z is 2x−y+2. Examples of such 1-2 carbon fluorocarbon gases include CF₄, CHF₃, CH₂F₂, C₂F₆, among others. The organic fluorocarbon gas may also comprise one or more higher molecular weight, 3-6 carbon fluorinated hydrocarbons having the general formula CₓH_{y}F_{z} wherein x is 3 to 6, y is 0 to 3, and z is 2x−y when the fluorinated hydrocarbon is cyclic, and z is 2x−y+2 when the fluorinated hydrocarbon is noncyclic. Examples of cyclic 3-6 carbon fluorocarbon compounds includes C₄H₂Fe and C₆F₁₂, wherein C₆F₁₂ and C₄H₂F₆ are the cyclic version, instead of linear version.

U.S. Pat. No. 7,794,616 discloses etching gas that includes a main gas composed of an unsaturated fluorocarbon-based gas. Another etching gas includes a main gas composed of an unsaturated fluorocarbon-based gas and an additive gas composed of a cyclic saturated fluorocarbon-based gas expressed by CₓF₂ₓ (x represents a natural number of 5 or larger). In this case, the additive gas is C₅F₁₀ gas or C₆F₁₂ gas. The inventors have found that, by adding to the main gas composed of an unsaturated fluorocarbon-based gas the additive gas composed of a cyclic saturated fluorocarbon-based gas expressed by CₓF₂ₓ (x represents a natural number of 5 or larger), it is possible to increase an etching rate while maintaining a high etching selectivity. In addition, in this case, the etching selectivity may be further increased compared with that in the case of adding the straight-chain saturated fluorocarbon-based gas. Furthermore, the additive gas may be C₅F₁₀ gas or C₆F₁₂ gas.

US2015294880 to Anderson et al. discloses fluorocarbon molecules for high aspect ratio oxide etch in which a number of hydrofluorocarbon gases including C₄H₂F₆ for etching silicon-containing layers. The QMS (quadrupole mass spectrometry) of C₄H₂F₆ (CAS #: 382-10-5) along with C₄F₈, C₄F₆ and other gases were disclosed. The primary species of C₄F₂F₆ was CF₃. They also disclose that different fluorocarbon etching gases, including isomers, have different etching properties and species in the QMS.

Thus, there is a need for both low GWP etching gas that function in an etching process as well as gasses that break down in the plasma and create low GWP byproducts.

### SUMMARY

Disclosed is an etching method for forming an aperture in a substrate, the method comprising:
exposing the substrate to an etching gas containing a non-cyclic C₆F₁₂;
converting the etching gas to a plasma;
allowing an etching reaction to proceed between the plasma and one or more silicon-containing films containing in the substrate so that the one or more silicon-containing films are selectively etched versus a patterned mask layer deposited on top of the one or more silicon-containing films to form the aperture therein and volatile by-products; and
removing the volatile by-products. The disclosed deposition method may include one or more of the following features:
   further comprising adding one or more hydrofluorocarbon or fluorocarbon etching gasses to the etching gas, wherein the one or more hydrofluorocarbon or fluorocarbon etching gasses are selected from C₄F₆, C₄F₈, C₄H₂F₆, CHF₃, CH₂F₂, CH₃F, CF₄, C₂F₆, C₃F₈, SF₆, NF₃, C₂F₄, C₃F₆, C₄F₁₀, C₅F₈, C₆F₆, C₁-C₇ CₓF_{y} molecule (x and y are integers), C₂H₂F₂, C₂H₅F, C₃H₇F, C₃H₂F₆, C₂HF₅, C₁-C₇ CₓF_{y}H_{z} molecule (where x, y and z are integers), or combination thereof;
   further comprising adding C₂H₂F₂ to the etching gas;
   further comprising adding H₂, SF₆, NF₃, NH₃, Cl₂, BCl₃, BF₃, Br₂, F₂, FNO, FNO₃, HBr, HCl, HI, IF₅, IF₇, HF, B₂H₆, or P-containing gases selected from PF₃, PCl₃, PBr₃, PH₃, POCl₃, PF₅, POF₃, PH₃ PCl₅, PBr₅, PF₂BrO, PCl₃O, PF₂Br, or PR₃ where R is an alkyl, or fluorinated alkyl groups, to the etching gas;
   further comprising adding O₂, CO, CO₂, NO, NO₂, N₂O, SO₂, H₂S, COS, O₃, OF₂, SOF₂, SO₂F₂, CₓO_{y}F_{z}SₘHₙ (where x, y, z, m and n are as integers) selected from (CF₃SO₂)₂O or CF₄SO₂, CₓO_{y}F_{z}NₘHₙ (where x, y, z, m and n are integers) selected from CF₃N═O, or CₓO_{y}F_{z} selected from COF₂, or C₂O₂F₂, CₓO_{y}F_{z}Hₘ (where x, y, z and m are integers) selected from alcohol, ketone, acidic, ester type molecule selected from CF₃OH, CF₃OCF₃, (CF₃)₂C═O, CF₃COOH or combinations thereof, to the etching gas;
   further comprising adding an inert gas to the etching gas, wherein the inert gas is selected from Ar, Kr, Xe, Ne, N₂, He or combination thereof;
   the non-cyclic C₆F₁₂ is an isomer of C₆F₁₂ with CAS No.: 2070-70-4, 1584-03-8, 755-25-9, 1584-00-5, 360-57-6, 1584-02-7, 3709-71-5, 1584-00-5, 3709-70-4, 359-72-8, 67483-02-7, 67899-37-0, 137202-54-1, 81018-66-8, 87743-93-9, 287101-12-6, 87744-03-4, 71186-98-6, 71186-97-5, 66319-89-9, 58621-70-8, 873536-26-6, or 13429-24-8;
   the non-cyclic C₆F₁₂ is an isomer of C₆F ₁₂ with CAS No.: 2070-70-4;
   the non-cyclic C₆F₁₂ is an isomer of C₆F₁₂ with CAS No.: 3709-71-5;
   the temperature of the substrate ranges from approximately −196° C. to approximately 300° C.;
   the temperature of the substrate ranges from approximately −196° C. to approximately 60° C.;
   the temperature of the substrate is below approximately −20° C.;
   the temperature of the substrate ranges from approximately −196° C. to approximately −50° C.;
   after the aperture is formed, the temperature of the substrate is increased to greater than −70° C.; and
   CO_{2eq} emissions of the volatile by-products are reduced compared to an etching process using etching gases with GWP₁₀₀>30.

Disclosed also is an etching method for forming an aperture in a substrate, the method comprising:
maintaining the substrate to a temperature ranging from approximately −196° C. to approximately 300° C.;
exposing the substrate to an etching gas containing a non-cyclic C₆F₁₂ (CAS No.: 2070-70-4, or CAS No.: 3709-71-5) into the reaction chamber;
adding C₂H₂F₂ to the etching gas;
converting the etching gas to a plasma;
allowing an etching reaction to proceed between the plasma and one or more silicon-containing films containing in the substrate so that the one or more silicon-containing films are selectively etched versus a patterned mask layer deposited on top of the one or more silicon-containing films to form the aperture therein; and
removing the volatile by-products. The disclosed deposition method may include one or more of the following features:
   further comprising adding a phosphorus containing gas and an HF containing gas;
   further comprising adding a fluorocarbon or hydrofluorocarbon gas, an oxidizing gas, and an inert gas;
   the temperature of the substrate ranges from approximately −196° C. to approximately 60° C.;
   the temperature of the substrate is below approximately −20° C.;
   the temperature of the substrate ranges from approximately −196° C. to approximately −50° C.;
   after the aperture is formed, the temperature of the substrate is increased to greater than −70° C.; and
   CO_{2eq} emissions of the volatile by-products are reduced compared to an etching process using etching gases with GWP₁₀₀ >30.

Disclosed also is an etching method for forming an aperture in a substrate, the method comprising:
maintaining the substrate to a temperature ranging from approximately −196° C. to approximately 300° C.;
exposing the substrate to an etching gas containing a non-cyclic C₆F₁₂ (CAS No.: 2070-70-4) into the reaction chamber;
adding C₂H₂F₂ to the etching gas;
converting the etching gas to a plasma;
allowing an etching reaction to proceed between the plasma and one or more silicon-containing films containing in the substrate so that the one or more silicon-containing films are selectively etched versus a patterned mask layer deposited on top of the one or more silicon-containing films to form the aperture therein; and
removing the volatile by-products. The disclosed deposition method may include one or more of the following features:
   further comprising adding a phosphorus containing gas and an HF containing gas;
   further comprising adding a fluorocarbon or hydrofluorocarbon gas, an oxidizing gas, and an inert gas;
   the temperature of the substrate ranges from approximately −196° C. to approximately 60° C.;
   the temperature of the substrate is below approximately −20° C.;
   the temperature of the substrate ranges from approximately −196° C. to approximately −50° C.;
   after the aperture is formed, the temperature of the substrate is increased to greater than −70° C.; and. CO_{2eq} emissions of the volatile by-products are reduced compared to an etching process using etching gases with GWP₁₀₀>30.

### Notation and Nomenclature

The following detailed description and claims utilize a number of abbreviations, symbols, and terms, which are generally well known in the art, and include:

As used herein, the indefinite article “a” or “an” means one or more.

As used herein, “about”, “around” or “approximately” in the text or in a claim means±10% of the value stated.

As used herein, “room temperature” in the text or in a claim means from approximately 20° C. to approximately 25° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from previous manufacturing steps. For example, the wafers may include silicon layers (including, but not limited to, crystalline, amorphous, porous, etc.), silicon-containing layers (including, but not limited to, SiO₂, SiN, SiON, SiCOH, etc.), metal or metal containing layers (including, but not limited to, copper, cobalt, ruthenium, tungsten, platinum, palladium, nickel, ruthenium, gold, etc.) or combinations thereof. Furthermore, the substrate may be planar or patterned. The substrate may be an organic patterned lodinated carbon layer film. The substrate may include layers of oxides that are used as dielectric materials in field effect transistor (FET) such as FinFET, MOFSET, GAAFET (Gate all-around FET), Ribbon-FET, Nanosheet, Forksheet FET, Complementary FET (CFET), MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. The substrate may include layers of alternating oxides (e.g., SiO) and nitrides (e.g., SiN). One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. The substrate may be any solid that has functional groups on its surface that are prone to react with the reactive head of a self-assembled monolayer (SAM), and may include without limitation 3D objects or powders.

The term “wafer” or “patterned wafer” refers to a wafer that has a stack of films on a substrate, at least the top-most film the stack of the films has topographic features or patterns that have been created in steps prior to etch and the patterned top-most film on is formed for pattern etch.

The term “processing” as used herein includes patterning, exposure, development, etching, deposition, cleaning, and/or removal of by-products, as required in forming a described structure.

The term of “deposit” or “deposition” refers to a series of processes where materials at atomic or molecular levels are deposited on a wafer surface or on a substrate from a gas state (vapor) to a solid state as a thin layer. Chemical reactions are involved in the process, which occur after creation of a plasma of the reacting gases or activation of the reacting gases by heat. The plasma may be capacitively coupled plasma (CCP), Inductively coupled plasma (ICP), electron cyclotron resonance (ECR) plasma, or a microwave plasma, but is not limited to. Suitable commercially available plasma etching chambers include but are not limited to the Lam Research Dual CCP reactive ion etcher Dielectric etch product family sold under the trademark Flex™ or the Tokyo Electron Tactras™ or Episode™ UL. The non-plasma exposure step may be performed in a different chamber than the plasma exposure step.

The term “aspect ratio” refers to a ratio of the height of a trench (or aperture) to the width of the trench (or the diameter of the aperture).

The term “high aspect ratio (HAR)” refers to an aspect ratio ranging from approximately 1:1 to approximately 500:1, preferably from approximately 20:1 to approximately 400:1.

The term “high aspect ratio etching” refers to the formation of a hole pattern in a target film by plasma etching method when aspect ratio of formed hole structures is exceeding value of 5.

Note that herein, the terms “film”, “layer” and “material” may be used interchangeably. It is understood that a film may correspond to, or related to a layer or a material, and that the layer may refer to the film and the material. Furthermore, one of ordinary skill in the art will recognize that the terms “film” or “layer” or “material” used herein refer to a thickness of some material laid on or spread over a surface and that the surface may range from as large as the entire wafer to as small as a trench or a line.

Note that herein, the terms “aperture”, “via”, “hole”, “trench” and “structure” may be used interchangeably to refer to an opening formed in a semiconductor structure.

As used herein, the abbreviation “NAND” refers to a “Negative AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “etch gas” and “etchant” may be used interchangeably when the etch gas is in a gaseous state at room temperature and ambient pressure. It is understood that an etch gas may correspond to, or be related to an etchant, and that the etchant may refer to the etch gas.

The terms “dope” or “doping” is used interchangeably to the process of incorporation of one or more elements into a film through various methods where that element may be chemically bond or physically bond, and the process of intentionally incorporating atoms of different elements into the film composition. The element(s) may be doped interstitial or substitutional within the film.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

As used herein, the term “hydrofluorocarbon” refers to a saturated or unsaturated function group containing carbon, fluoride and hydrogen atoms.

As used herein, the term “fluorocarbon” refers to a saturated or unsaturated function group containing fluorine and carbon atoms.

As used herein, the term “fluorochemical” is used interchangeably with the terms hydrofluorocarbon and fluorocarbon.

As used herein, the term “GWP” refers to Global Warming Potentials, typically on a 100 year timescale and comparing the global warming potential to CO₂.

As used herein, the term “GWP₁₀₀” is the GWP over 100 years.

As used herein, the term “CO_{2eq}” or “CO₂e” is CO₂ equivalent emission, i.e., the amount of greenhouse gas emissions comparable to CO₂ by using the mass of the species being emitted and multiplying by the GWP of the species. This allows the equivalent comparison of the emissions of a process between two different etching gases utilizing the GWP of each molecule.

As used herein, “CO₂ emission (CO₂e)” or “CO₂ equivalent emission (CO_{2eq})” are used interchangeably to refer to the relative global warming impactful emissions.

As used herein, the term “etching gas” or “etchant” refers to one or more gaseous material(s) that are performing etching. The source of the material(s) in a container that provides the vapors to do the etching may contain a gas, liquid or solid state of the material(s) and/or combinations thereof. The etching gas and/or etchant may be one gaseous material or chemical. The etching gas and/or etchant may be a mixture of more than one gaseous materials or chemicals.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term that means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a column graph of a comparison of etching rates between C₆F₁₂, C₄F₈ and C₄F₆ applying to common materials used in semiconductor processing, a-C, SiO₂ and SiN, respectively;

FIG. 2 is a column graph of the measurements of CO₂ equivalent emissions from the plasma etch chamber (pre-abatement) utilizing an FTIR and normalized the results to the SiO₂ etching rate, using the same process conditions as FIG. 1;

FIG. 3 is a column graph of a comparison of etching rates between C₆F₁₂, C₄F₈ and C₄F₆ each were individually mixed with a hydrofluorocarbon gas CH₂F₂ along with O₂ and Ar applying to a-C, SiO₂ and SiN, respectively;

FIG. 4 is a column graph of normalized CO₂ equivalent emissions of the same conditions as FIG. 3;

FIG. 5 is a column graph of a comparison of etching rates between C₆F₁₂, C₄F₈ and C₄F₆ each were individually mixed with a hydrofluorocarbon gas C₂H₂F₂ along with O₂ and Ar applying to a-C, SiO₂ and SiN, respectively;

FIG. 6 is a column graph of normalized CO₂ equivalent emissions of the same conditions as FIG. 5;

FIG. 7 is a pie graph of QMS of C₆F₁₂ CAS #: 2070-70-4;

FIG. 8 is pie graph of QMS of C₄H₂F₆;

FIG. 9 is pie graph of QMS of C₄F₈; and

FIG. 10 is pie graph of QMS of C₄F₆.

### DESCRIPTION OF PREFERRED EMBODIMENTS

Disclosed are methods of using fully fluorocarbons (PFC's) and hydrofluorocarbon (HFC's) extensively to etch silicon-containing materials in semiconductor manufacturing. PFC's and HFC's are a source of both “F” for etching the silicon (creating the SiF₄ byproduct) and polymer for forming sidewall protection in patterning. However, PFC and HFC gases of commonly used often have high Global Warming Potentials (GWP). Table 1 below includes GWPs of commonly used etching gases in the semiconductor industry along with other molecules that may be plasma byproducts as well as other chemistries. The PFC molecules such as C₂F₆, C₃F₈, C₄F₈, etc. are good SiO₂ etchants. However, the PFC's specifically have very high GWPs. Additionally, byproducts from etch may include NO₂, CO, CO₂, COF₂, SiF₄, etc.

TABLE 1
GWP₁₀₀ Values

| Gas | GWP₁₀₀ |
|---|---|
| CHF₃ | 12400 |
| C₂F₆ | 11100 |
| C₃F₈ | 9290 |
| C₄F₈ | 9540 |
| C₅F₁₂ | 9220 |
| C₆F₁₄ | 8620 |
| CF₄ | 6630 |
| C₅F₈ | 90 |
| CH₂F₂ | 677 |
| NO₂ | 265 |
| CO | 2.1 |
| C₄H₂F₆ | 4 |
| CO₂ | 1 |
| COF₂ | <1 |
| CF₃I | <1 |
| C₄F₆ | <1 |
| C₂H₂F₂ | <1 |
| C₃F₆ | <1 |

The primary way to reduce the GWP of a fluorochemical gas is to add a double bond. As such, one may compare the GWP of C₃F₈ vs C₃F₆, C₅F₁₂ vs C₅F₈, etc. However, the addition of a double bond may cause the molecule to be more polymerizing in plasma resulting in lower SiO₂ etching rate but potentially with higher selectivity to mask material such as carbon materials like a-C. Ideally, one would like a low GWP through the addition of a double bond and an increased etching rate. Fully fluorinated molecules (PFC's) are ideal for etching SiO₂ patterns with various mask materials like a-C. For etching nitride material, or alternating layers of SiO₂ and SiN, such as used in 3D NAND technology, one may add a hydrofluorocarbon gas as the H is beneficial to etch the SiN layers. Thus, one may mix C₄F₆ and/or C₄F₈ with a hydrofluorocarbon gas such as CHF₃, CH₂F₂, CH₃F, etc. There exists hydrofluorocarbon gases with a double bond and CF₃ moieties such as C₄H₂F₆ that have low GWP and should provide good etching performance according to the literature. Here, C₆F₁₂ is disclosed as an etching gas for etching of silicon materials in plasma etch process to manufacture semiconductor chips, such as for 3D NAND flash and DRAM chip manufacturing to replace high GWP etching gasses. Such high aspect ratio structures are very challenging to etch using conventional fluorocarbon plasma etch methods especially as going to new technology nodes. Other applications could include plasma etch processes in logic etch (BEOL, etc.). The other issue with the traditional fluorocarbon and hydrofluorocarbon gasses is the traditional fluorocarbon and hydrofluorocarbon gasses may have a high GWP but also when exposed to the high power plasma the traditional fluorocarbon and hydrofluorocarbon gasses will break apart and potentially form species that also have high GWP as these species are in the radical and ion form in the plasma chamber they can react with each other and with the wafer and other internal components of the chamber, forming new species. Due to the complexities of the plasma process and the breakdown species it is difficult to predict the byproducts and the recombination byproducts of the emissions. These species then exit the plasma etch chamber and are emitted. In some instances, these species may pass through a scrubbing device but these species have various efficiencies within the scrubbing device and they may not be scrubbed 100%. For example, Beu et al. (Reduction of Perfluorocompound (PFC) Emissions: 2005 State-of-the-Technology Report. International SEMATECH Manufacturing Initiative Technology Transfer #05104693A-ENG) reports a wide range of breakdown efficiencies for commonly used abatement systems in the semiconductor industry. The emissions of the etching process may be qualified and quantified using QMS and FTIR along with other measurement methods. The emissions of the etching process may utilize various abatement processes including plasma, thermal burning process (for example using CH₄), adsorption processes, water neutralization, and catalytic reactions. Additives such as O₂, H₂O, O₃, etc. may be added to the etch emissions to react with and further reduce the GWP of the emissions. For example, by oxidizing the carbon species to CO, CO₂, and COF₂.

Non-cyclic C₆F₁₂ is particularly attractive due to its very low GWP₁₀₀ of ˜30 according to Kopylov et al. in “Characteristics of Impact on the Atmosphere of Perfluorisohexenes-Promising Components of Gas Extinguishing Compositions” due to incorporation of a C═C double bond whereas other traditional etching gases have very high GWP, such as C₄F₈ with a GWP₁₀₀ of 9540. In addition, cyclic C₆F ₁₂ is expected to have high GWP around 10,000 according to Simmonds et.al in “The background atmospheric concentrations of cyclic perfluorocarbon tracers determined by negative ion-chemical ionization mass spectrometry”. Here, C₆F₁₂ is disclosed to be used as the sole fluorocarbon gas or with other fluorocarbon or hydrofluorocarbon etching gas to etch SiO₂ and SiN layers selective to mask materials such as a-C. For example, the addition of hydrofluorocarbon gas with low GWP such as C₂H₂F₂ is especially beneficial when mixing with C₆F₁₂. The addition of the hydrofluorocarbon gas aids in the etching of the SiN layers as well as providing polymerizing gas for selectivity to a-C mask materials. Traditional etch gases include octafluorocyclobutane (cC₄F₈), hexafluoro-1,3-butadiene (C₄F₆), CF₄, CH₂F₂, CH₃F, and/or CHF₃. It is well known that selectivity and polymer deposition rate increase as the ratio of C:F increases (i.e., C₄F₆>C₄F₈>CF₄). See, e.g., U.S. Pat. No. 6,387,287 to Hung et al. However, the C:F ratio may not directly predict the etching performance. Anderson et al. in US2015294880 teaches that C:F ratio of the etching gas does not directly correspond to the C:F ratio in the deposited polymer. For example molecules with the same chemical formula but different structures may result in polymers with different C:F ratio, different deposition rates, different fragments as measured by mass spectrometry, and different etch rates and selectivity to a variety of materials (SiO₂, a-C, photoresist, SiN). For very high aspect ratio etching applications, for example >20:1 for applications such as 3D NAND or DRAM they may not have sufficient performance. The —CₓF_{y} polymers on sidewalls may be susceptible to etching through ion bombardment and F* reaction with the Si material. As a result, the etched patterns may not be vertical and the etch structures may show bowing, change in dimensions, pattern collapse and/or increased roughness. Temperature is an important parameter of the etching process. High aspect ratio plasma etch is very challenging. One new emerging technology is the use of very low substrate temperature; usually around −70° C. below the traditional etch chamber limitations of −20° C. In this case much less polymerizing gasses are needed thus speeding up the etch and allowing good profile control because the etch byproducts themselves act as sidewall protection. Etching profile may be controlled at lower temperatures by limiting the volatility byproducts (i.e., SiF₄ is volatile above −86° C., CO₂ is volatile above −70° C., other etch byproducts are not volatile at these temperatures) to control etch profile to highly vertical features. On the other hand, temperature affects the sticking coefficients of the radicals therefore affecting polymerization, etching rates and selectivities. Both low temperature etch and high temperature etch are important processes in semiconductor etching processes. For example, wafer temperature up to 60° C. is commonly used for dielectric etching processes. Chamber pressure affects the residence time of the various species in the chamber as well as number of molecules/radicals/ions in the chamber. Pressure is closely tied to etch rates, selectivities and profile of pattern etch process. Typical range is from 1 mtorr to 500 mtorr.

The molecules have the formula C₆F₁₂ are preferably non-cyclic containing a double bond listed in Table 2. The most preferable C₆F₁₂ is CAS No.: 2070-70-4 and CAS No 3709-71-5.

TABLE 2
Non-cyclic Isomers of C₆F₁₂ with a double bond

| Name | CAS# | Molecule structure |
|---|---|---|
| Perfluoro-4-methyl-2- pentene | 2070-70-4 | 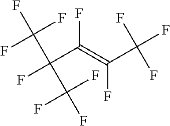 [SMILES: F/C(=C(/F)C(F)(C(F)(F)F)C(F)(F)F)C(F)(F)F] |
| Perfluoro-2-methyl-2- pentene | 1584-03-8 | 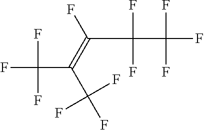 [SMILES: FC(=C(C(F)(F)F)C(F)(F)F)C(F)(F)C(F)(F)F] |
| perfluorohex-1-ene | 755-25-9 | 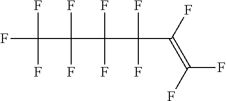 [SMILES: FC(F)=C(F)C(F)(F)C(F)(F)C(F)(F)C(F)(F)F] |
| PERFLUOROHEXENE-2 | 1584-00-5 | 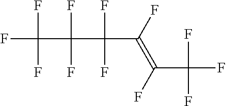 [SMILES: F/C(=C(/F)C(F)(F)C(F)(F)C(F)(F)F)C(F)(F)F] |
| tetrakis(trifluoromethyl)- ethylene | 360-57-6 | 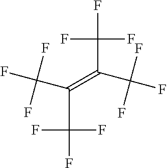 [SMILES: FC(F)(F)C(=C(C(F)(F)F)C(F)(F)F)C(F)(F)F] |
| 1,1,1,2,2,3,4,5,5,6,6,6- Dodecafluoro-3-hexene | 1584-02-7 | 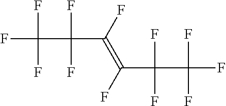 [SMILES: F/C(=C(/F)C(F)(F)C(F)(F)F)C(F)(F)C(F)(F)F] |
| trans-4-(Trifluoromethyl)- perfluoro-2-pentene | 3709-71-5 | 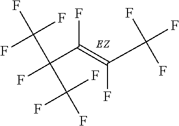 [SMILES: F/C(=C(/F)C(F)(C(F)(F)F)C(F)(F)F)C(F)(F)F] |
| Perfluorohexene-2 | 1584-00-5 | 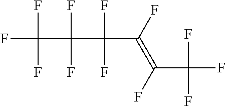 [SMILES: F/C(=C(/F)C(F)(F)C(F)(F)C(F)(F)F)C(F)(F)F] |
| trans-perfluoro-4-methyl- pent-2-ene | 3709-70-4 | 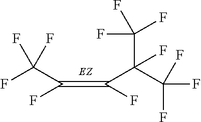 [SMILES: F/C(=C(\F)C(F)(C(F)(F)F)C(F)(F)F)C(F)(F)F] |
| 1-Pentene, nonafluoro-2- (trifluoromethyl)- | 359-72-8 | 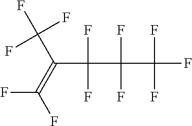 [SMILES: FC(F)=C(C(F)(F)F)C(F)(F)C(F)(F)C(F)(F)F] |
| 1,1,1,2,4,4,5,5,5- Nonafluoro- 3-(trifluoromethyl)- 2-pentene | 67483-02-7 | 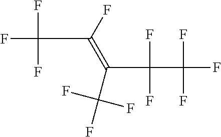 [SMILES: F/C(=C(/C(F)(F)F)C(F)(F)C(F)(F)F)C(F)(F)F] |
| Perfluorohexene-2 | 67899-37-0 | 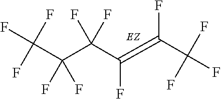 [SMILES: F/C(=C(/F)C(F)(F)C(F)(F)C(F)(F)F)C(F)(F)F] |
| 1,1,2,4,4,4-Hexafluoro- 3,3-bis(trifluoromethyl)- 1-butene | 137202-54-1 | 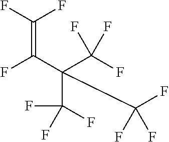 [SMILES: FC(F)=C(F)C(C(F)(F)F)(C(F)(F)F)C(F)(F)F] |
| 3-Hexene, 1,1,1,2,2,3,4,5,5,6,6,6- dodecafluoro-, (3E)- | 81018-66-8 | 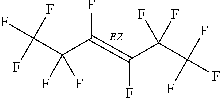 [SMILES: F/C(=C(/F)C(F)(F)C(F)(F)F)C(F)(F)C(F)(F)F] |
| (2E)-1,1,1,2,4,4,5,5,5- Nonafluoro-3-(trifluoro- methyl)-2-pentene | 87743-93-9 | 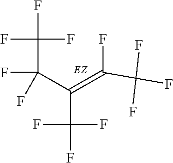 [SMILES: F/C(=C(/C(F)(F)F)C(F)(F)C(F)(F)F)C(F)(F)F] |
| 1,1,2,3,3,4,5,5,5- Nonafluoro-4- (trifluoromethyl)- 1-pentene | 287101-12-6 | 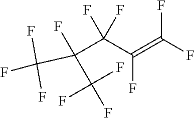 [SMILES: FC(F)=C(F)C(F)(F)C(F)(C(F)(F)F)C(F)(F)F] |
| 2-Pentene, 1,1,1,2,4,4,5,5,5- nonafluoro-3- (trifluoromethyl)-, (Z)- | 87744-03-4 | 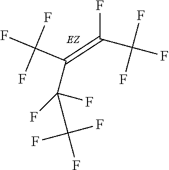 [SMILES: F/C(=C(\C(F)(F)F)C(F)(F)C(F)(F)F)C(F)(F)F] |
| 3-Hexene, 1,1,1,2,2,3,4,5,5,6,6,6- dodecafluoro-, (Z)- | 71186-98-6 | 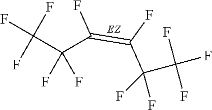 [SMILES: F/C(=C(\F)C(F)(F)C(F)(F)F)C(F)(F)C(F)(F)F] |
| 2-Hexene, 1,1,1,2,3,4,4,5,5,6,6,6- dodecafluoro-, (Z)- | 71186-97-5 | 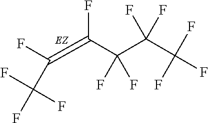 [SMILES: F/C(=C(\F)C(F)(F)C(F)(F)C(F)(F)F)C(F)(F)F] |
| 2-Butene, 1,1,1,4,4,4-hexafluoro- 2,3-bis(trifluoromethyl)-, | 66319-89-9 | 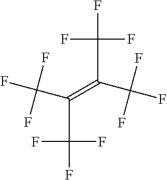 [SMILES: FC(F)(F)C(=C(C(F)(F)F)C(F)(F)F)C(F)(F)F] |
| 1,1,3,4,4,4-Hexafluoro- 2,3-bis(trifluoromethyl)- 1-butene | 58621-70-8 | 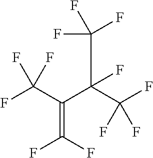 [SMILES: FC(F)=C(C(F)(F)F)C(F)(C(F)(F)F)C(F)(F)F] |
| 3-(Difluoromethylene)- 1,1,1,2,2,4,4,5,5,5- decafluoropentane | 873536-26-6 | 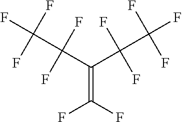 [SMILES: FC(F)=C(C(F)(F)C(F)(F)F)C(F)(F)C(F)(F)F] |
| 1-Propene, 1,1,2,3,3,3-hexafluoro-, dimer | 13429-24-8 | 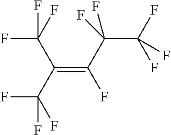 [SMILES: FC(=C(C(F)(F)F)C(F)(F)F)C(F)(F)C(F)(F)F] |

TABLE 3
Cyclic isomers of C₆F₁₂ that likely have high GWP and do not contain a double bond.

| | | | Boiling point |
|---|---|---|---|
| Name | CAS No. | Structure | (° C.) |
| Perfluoro(methyl- cyclopentane) | 1805-22-7 | 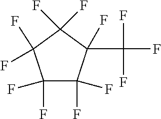 [SMILES: FC(F)(F)C1(F)C(F)(F)C(F)(F)C(F)(F)C1(F)F] | 48 |
| Perfluoro-1,2- dimethylcyclo- butane | 2994-71-0 | 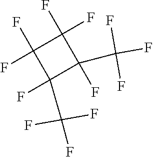 [SMILES: FC(F)(F)C1(F)C(F)(F)C(F)(F)C1(F)C(F)(F)F] | 45 |
| Perfluorocyclo- hexane | 355-68-0 | 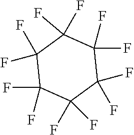 [SMILES: FC1(F)C(F)(F)C(F)(F)C(F)(F)C(F)(F)C1(F)F] | 59-60 |

Considering the examples of the hydrofluorocarbon etching compounds and their isomers listed in Table 2, and the study described in Examples that follow, it may be summarized that the vapor of the non-cyclic C₆F₁₂ having a C═C double bond may be used for plasma etching process as an etching gas with very low GWP₁₀₀, in particular any non-cyclic C₆F₁₂'s having a C═C double bond that are include in Table 2, most preferably, C₆F ₁₂ whose CAS number is CAS No.: 2070-70-4 and CAS No 3709-71-5.

The disclosed PFC's and HFC's etching gases that have very low GWP₁₀₀ include non-cyclic C₆F₁₂ and theirisomers, preferably the non-cyclic C₆F₁₂ (CAS No.: 2070-70-4 and CAS No 3709-71-5), used in the etching process and/or used in the chamber conditioning process.

The disclosed non-cyclic C₆F₁₂ (CAS No.: 2070-70-4 and CAS No 3709-71-5) may be used in the etching process and/or used in the chamber conditioning process.

During the etching process, temperature of the substrate may range-196° C. to 300° C., preferably-20° C. to 150° C. The substrate may be cooled by a variety of sources including commercially available chillers or other methods such as liquid N₂.

Reaction chamber wall temperature may be around >20° C., preferably <50° C. The reaction chamber wall temperature may be around room temperature or larger but less than 50° C. depending on process requirements.

Pressure in the reaction chamber may range from 1 mtorr to 10,000 mtorr for a typical dielectric etching process.

One or more hydrofluorocarbon or fluorocarbon etching gasses that may be added to non-cyclic C₆F₁₂ are selected from C₄F₆, C₄F₈, C₄H₂F₆, CHF₃, CH₂F₂, CH₃F, CF₄, C₂F₆, C₃F₈, SF₆, NF₃, C₂F₄, C₃F₆, C₄F₁₀, C₅F₈, C₆F₆, C₁-C₇ CₓF_{y} molecule (x and y are integers), C₂H₂F₂, C₂H₅F, C₃H₇F, C₃H₂F₆, C₂HF₅, C₁-C₇ CₓF_{y}H_{z} molecule (where x, y and z are integers), or combination thereof; Preferably C₂H₂F₂.

Plasma may be generated with a RF power ranging from about 1 W to about 100,000W. The plasma may be generated remotely or within the reactor itself. RF frequency of THE plasma may range from 40 KHz to 1GHz.

The etching process using non-cyclic C₆F₁₂ may comprises the step of prior to activating the plasma, sequentially or simultaneously exposing the substrate to a co-reactant and/or an additive.

Other gases that act as the co-reactant and/or additives may be added to non-cyclic C₆F₁₂, which include H₂, SF₆, NF₃, NH₃, Cl₂, BCl₃, BF₃, Br₂, F₂, FNO, FNO₃, HBr, HCl, HI, IF₅, IF₇, B₂H₆, HF, P containing gases selected from PF₃, PCl₃, PBr₃, PH₃, POCl₃, PF₅, POF₃, PH₃ PCl₅, PBr₅, PF₂BrO, PCl₃O, PF₂Br, or PR₃ where R is an alkyl, or fluorinated alkyl groups. The exemplary PR₃ is P(CF₃)₃.

The other gases also include an inert gas selected from Ar, Kr, Xe, Ne, N₂, He or combination thereof.

The other gases may include O₂, CO, CO₂, NO, NO₂, N₂O, SO₂, H₂S, COS, O₃, OF₂, SOF₂, SO₂F₂, CₓO_{y}F_{z}SₘHₙ (where x, y, z, m and n are as integers) such as (CF₃SO₂)₂O or CF₄SO₂, CₓO_{y}F_{z}NₘHₙ (where x, y, z, m and n are integers) such as CF₃N═O, or CₓO_{y}F_{z} such as COF₂, or C₂O₂F₂, CₓO_{y}F_{z}Hₘ (where x, y, z and m are integers) such as alcohol, ketone, acidic, ester type molecule selected from CF₃OH, CF₃OCF₃, (CF₃)₂C═O, CF₃COOH or combinations thereof, to add to the non-cyclic C₆F₁₂.

The reaction chamber may be any enclosure or chamber within a device in which etching methods take place such as, and without limitation, reactive ion etching (RIE), CCP with single or multiple frequency RF sources, inductively coupled plasma (ICP), or microwave plasma reactors, or other types of etching systems capable of selectively removing a portion of the silicon-containing film or generating active species or depositing films.

Substrate may be Si containing, such as Si, SiO₂, SiN, SiOC, SiC, SiCN, or any of these materials with dopants of Boron, Phosphorus, and of any metal. One example is a multilayer of SiO and SiN as used in 3D NAND applications.

Mask material used herein may be amorphous carbon (a-C) or doped amorphous carbon, or Si or SiN, Al, AlO, Ti, TiO, TiN, AlN, and other metal, metal oxide masks, Silicon oxide containing, metal nitride, and silicon nitride containing mask.

During the etch process, if the temperature of the substrate was cooled to cold temperatures then post etch the substrate will be warmed up, for example post etch the substrate is warmed up to >−70° C. such that byproducts of the etching reaction are evaporated away into a vacuum exiting the chamber when etching at cryogenic temperatures (<−70° C.).

Not only does C₆F₁₂ have a much lower GWP than standard fluorochemical etching gases, it also produces lower CO₂ equivalent emissions from the etching process. The disclosed plasma etch method uses C₆F₁₂ as etching gas to produce apertures, such as channel holes, gate trenches, staircase contacts, capacitor holes, contact holes, contact etch, slit etch, self-aligned contact, self-aligned vias, super vias etc., in silicon-containing films. The resulting apertures may have an aspect ratio ranging from approximately 5:1 to approximately 500:1, preferably from approximately 20:1 to approximately 400:1. The resulting apertures may have a diameter ranging from approximately 0.1 nm to approximately 500 nm; preferably, ranging from approximately 0.1 nm to approximately 500 nm; more preferably being less than 100 nm. The resulting apertures may have an aspect ratio above 1:1, preferably above 5:1, more preferably above 10:1, even more preferably above 20:1. The resulting apertures may have an aspect ratio ranging from 1:1 to 5:1. For example, one of ordinary skill in the art will recognize that a channel hole etch produces apertures in the silicon-containing films having an aspect ratio greater than 50:1.

The disclosed is the method of reducing the CO_{2eq} emissions from an etching process to etch a silicon containing layer. The emissions of the etching process may be qualified and quantified using QMS and FTIR along with other measurement methods. The emissions of the etching process may utilize various abatement processes including plasma, thermal burning process (for example using CH₄), adsorption processes, water neutralization, and catalytic reactions. Additives such as O₂, H₂O, O₃, etc. may be added to the etch emissions to react with and further reduce the GWP of the emissions (for example by oxidizing the carbon species to CO, CO₂, and COF₂) or to cause the emissions to be more easily abated (such as converting F₂ to HF using H₂O).

The disclosed non-cyclic C₆F₁₂, for example CAS No.: 2070-70-4, may be supplied in a gas cylinder, steel canister, bubbler, or a similar appropriate package at a variety of fill quantities, pressure and specifications. Since C₆F₁₂ (boiling point 49° C.) is a liquid it may be delivered either in the gas phase or liquid phase to a vaporizer to the etching chamber. Preferably the material has a low moisture content of <40 ppm, preferably <10 ppm. C₆F₁₂ may be purified to remove critical impurities such as other fluorocarbons, hydrofluorocarbons, chlorofluorocarbons (CFC's), impurities from the air (N₂, O₂, CO₂), moisture (H₂O), HF other hydrocarbons (CH₄, etc.), using distillation, adsorption using molecular sieves, or other commonly known methods in the art. Some impurities may form azeotropes thus other purification methods may need to be employed using chemical means to separate them.

### EXAMPLES

A more detailed description of the disclosed methods through examples is provided as follows. However, the disclosed methods is not limited to presented examples in any way and process conditions, process gas mixture, combination and proportion of gases in the gas mixture, workpiece and plasma etching chamber itself may be altered.

In the following Examples, the primary plasma etching source may be a CCP plasma but may also include other sources such as ICP, microwave, ECR, etc. The plasma may be used in a continuous source or as a pulsed plasma of a certain frequency and duty cycle. The temperature of substrate surface may be cooled down or elevated by a chiller, or by liquid N₂ supply and heating stage. Additional fluorocarbon gases may be added to slightly tune the etching performance. Additional inert gases may be added such as Kr, Xe, Ne, Ne as well as hydrogen source gases such as H₂, and hydrocarbons. The mask material may include TiN or other metal nitride materials, SiN, Si, carbon materials, or the like. In the following Examples, for comparison purpose, the etching and emission performance of CH₂F₂ and C₄H₂F₆, which are disclosed in US 2023/0127467, are also presented. The examples were carried out in a 300 mm CCP plasma etcher. All reported CO_{2eq} emissions were normalized to the SiO₂ etching rate except where noted and are all pre-abatement. The RF source power was 950/200 W and bias power was 6000/200 W in all experiments (meaning the power is cycling between the high and low power at a certain frequency). All etching experiments with C₆F₁₂ was the CAS #2070-70-4 isomer.

### Example 1

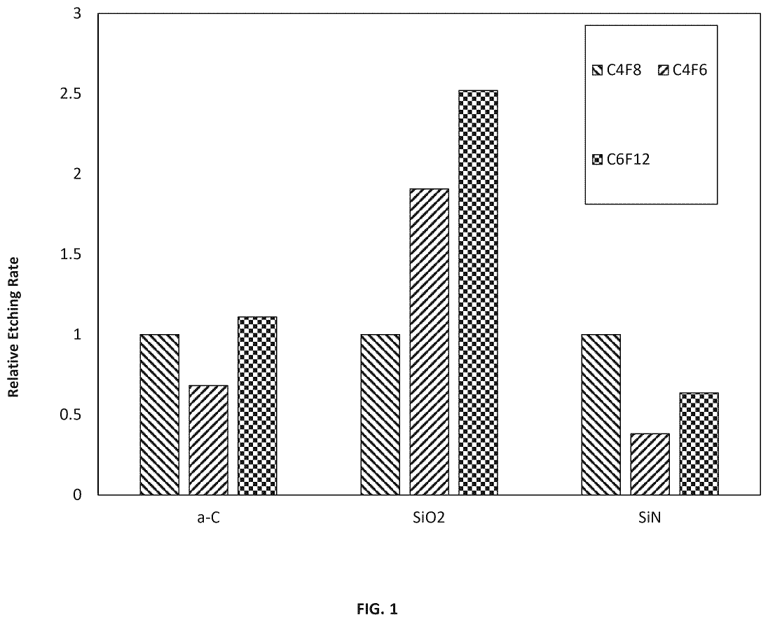

The etching rates for the process conditions described below in Table 4 to 3 common materials used in semiconductor processing, SiO₂, SiN and a-C, were compared. As may be seen in FIG. 1 from the results C₆F₁₂ has considerably higher SiO₂ etching rate than C₄F₈ and C₄F₆ and a selectivity to a-C of 4.5 (C₆F₁₂), 5.5 (C₄F₆), and 2.0 (C₄F₈). Since C₄F₈ and C₆F₁₂ both have the same C/F ratio (C/F=0.5) this is surprising. C₄F₆, with its 2 double bonds has lower SiO₂ etching rate than C₆F₁₂ but slightly higher selectivity due to its lower a-C etching rate.

TABLE 4

| HAR | | | |
|---|---|---|---|
| Channel Hole Etch | C₄F₈ | C₄F₆ | C₆F₁₂ |
| Pressure [mTorr] | 22 | 22 | 22 |
| C₄F₈ flow rate (FR) [sccm] | 20 | 0 | 0 |
| C₄F₆ FR [sccm] | 0 | 20 | 0 |
| C₆F₁₂ FR [sccm] | 0 | 0 | 20 |
| O₂ FR [sccm] | 40 | 40 | 40 |
| Ar FR [sccm] | 150 | 150 | 150 |
| Wafer T [° C.] | 20 | 20 | 20 |

### Example 2

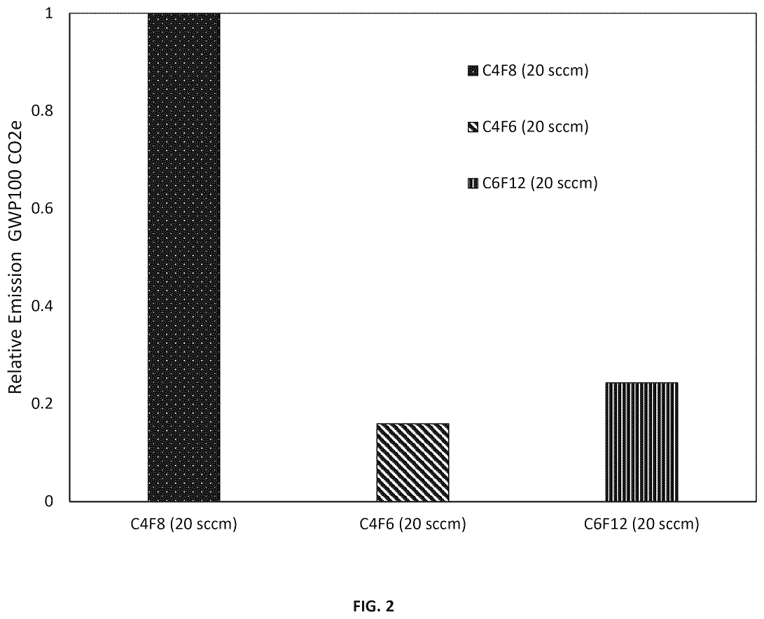

Using the same process conditions as Example 1, the CO_{2eq} emissions from the plasma etch chamber utilizing an FTIR and normalized the results to the SiO₂ etching rate were measured and then made relative to the CO_{2eq} emissions of C₄F₈. It has been found that the CO_{2eq} emissions for C₄F₆ and C₆F₁₂ were similar but the emissions of C4F8 were considerably higher as shown in FIG. 2.

### Example 3

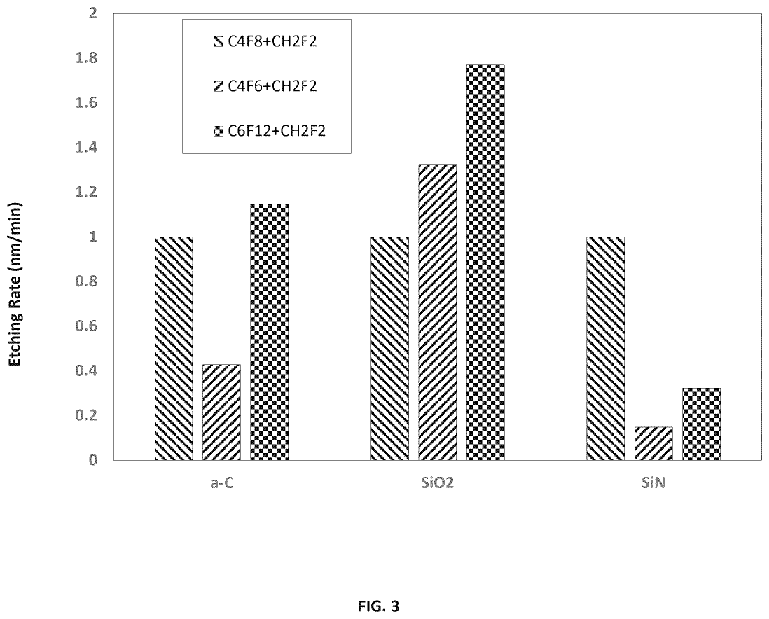

In a plasma etch chamber C₄F₈, C₄F₆ or C₆F₁₂ were individually mixed with a hydrofluorocarbon gas, CH₂F₂ along with O₂ and Ar under similar conditions described below in Table 5 and their etching rates of SiO₂, SiN, and a-C were compared. The addition of a hydrogen containing gas could be useful for etching SiN layers, such as in 3DNAND SiO₂/SiN etching process. As may be seen in FIG. 3, the recipe containing C₆F₁₂ had a higher SiO₂ etching rate than the other gases showing a significant throughput benefit. The selectivity to a-C are C₄F₈=4.4, C₄F₆=13.5, C₆F₁₂=6.8. This shows C₆F₁₂ maintains higher selectivity as compared to C₄F₈ though still lower than C₄F₆ due to the 2 double bonds of C₄F₆. Therefore, while C₆F₁₂+CH₂F₂ has etching benefits compared to C₄F₈+CH₂F₂ it is still lower selectivity as compared to C₄F₆. In addition, the combination of C₆F₁₂+CH₂F₂ surprisingly gives higher etching rate of SiN as compared to C₄F₆+CH₂F₂ which may be beneficial to SiO/SiN alternating layer etching process.

TABLE 5

| HAR | | | |
|---|---|---|---|
| Channel Hole Etch | C₄F₈ + CH₂F₂ | C₄F₆ + CH₂F₂ | C₆F₁₂ + CH₂F₂ |
| Pressure [mTorr] | 22 | 22 | 22 |
| C₄F₈ FR [sccm] | 20 | 0 | 0 |
| C₄F₆ FR [sccm] | 0 | 20 | 0 |
| CH₂F₂ FR [sccm] | 20 | 20 | 20 |
| C₆F₁₂ FR [sccm] | 0 | 0 | 20 |
| O₂ FR [sccm] | 40 | 40 | 40 |
| Ar FR [sccm] | 150 | 150 | 150 |
| Wafer T [° C.] | 20 | 20 | 20 |

### Example 4

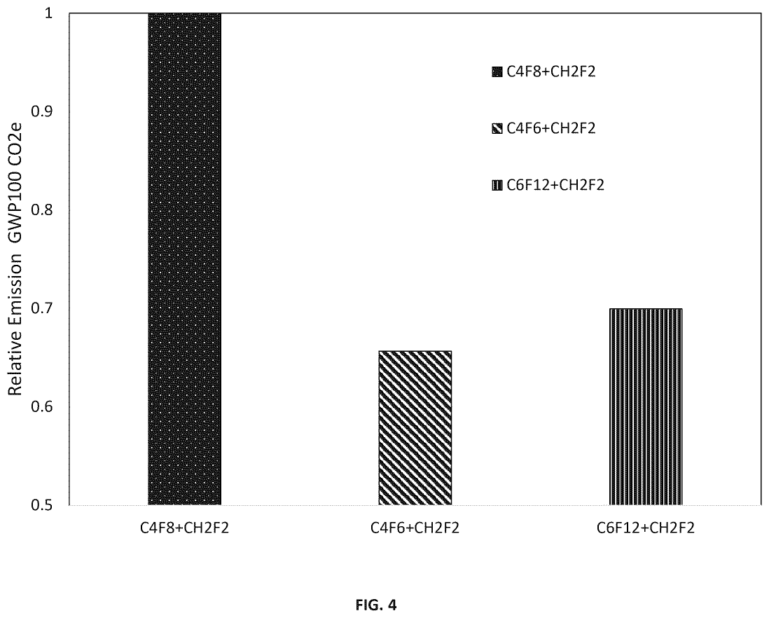

The normalized CO_{2eq} emissions relative to C₄F₈+CH₂F₂ of the same conditions were compared. As may be seen from FIG. 4 the addition of CH₂F₂ did not change the order of CO_{2eq} emissions from the individual gasses where the C₄F₈ containing process was much greater than C₆F₁₂ and C₄F₆ was slightly lower. The CO_{2eq} emissions of the C₆F₁₂ process was 30% lower than the equivalent C₄F₈ process.

### Example 5

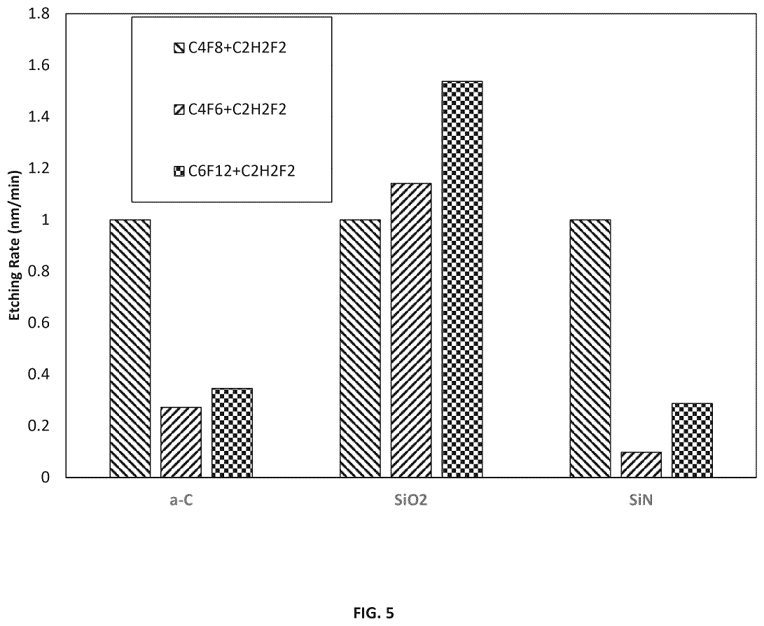

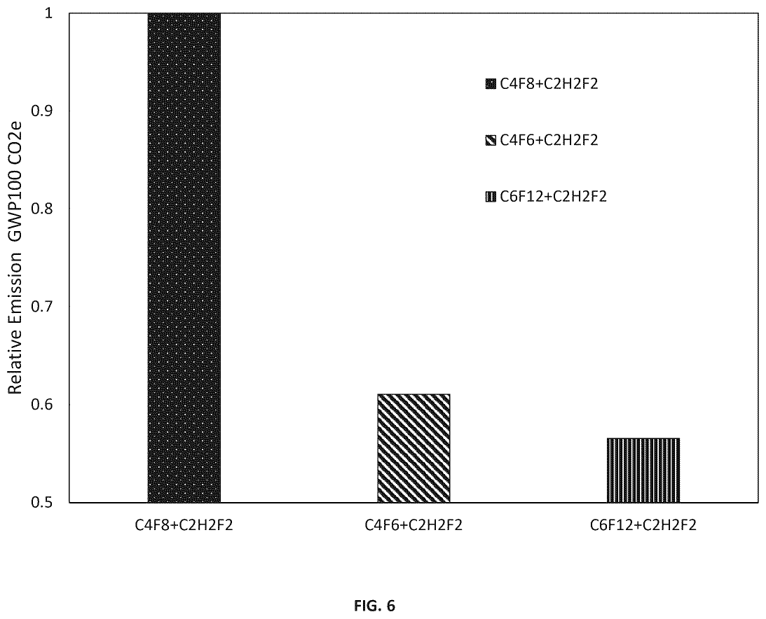

Similar to Example 3 and 4 the same gasses were mixed with C₂H₂F₂ (CAS # 75-38-7) rather than CH₂F₂ under conditions described below in Table 6. Note the flow rate (FR) of C₂H₂F₂ was half that of CH₂F₂ but gives the same mole quantity of carbon in the process. The results are shown in FIG. 5 and FIG. 6 for etching rates and emissions respectively. The selectivity of SiO₂/a-C are as follows: C₆F 12:20 C₄F₆: 18.8 C₄F₈: 4.5. Surprisingly the combination of C₆F₁₂ and C₂H₂F₂ gave higher SiO₂ etching rates and higher selectivity of SiO₂/a-C than either C₄F₈ or C₄F₆ that is very beneficial to such an etching process. This is different from the results compared to CH₂F₂ where the selectivity trends did not change when added to each of the individual gasses. Therefore, the combination of C₆F₁₂ +C₂H₂F₂ gave unexpected improved etching performance as compared to the other etching gas combinations.

TABLE 6

| HAR | | | |
|---|---|---|---|
| Channel Hole Etch | C₄F₈ + C₂H₂F₂ | C₄F₆ + C₂H₂F₂ | C₆F₁₂ + C₂H₂F₂ |
| Pressure [mTorr] | 22 | 22 | 22 |
| C₄F₈ FR [sccm] | 20 | 0 | 0 |
| C₄F₆ FR [sccm] | 0 | 20 | 0 |
| C₂H₂F₂ FR [sccm] | 10 | 10 | 10 |
| C₆F₁₂ FR [sccm] | 0 | 0 | 20 |
| O₂ FR [sccm] | 40 | 40 | 40 |
| Ar FR [sccm] | 150 | 150 | 150 |
| Wafer T [° C.] | 20 | 20 | 20 |

### Example 6

The normalized CO_{2eq} emissions were measured for the etching process showing in Example 5 and FIG. 6 and are listed below and made relative to the C₄F₈+C₂H₂F₂ emissions. The CO_{2eq} emissions from least to greatest were C₆F₁₂ +C₂H₂F₂<C₄F₆+C₂H₂F₂<<C₄F₈+C₂H₂F₂. Even though C₆F₁₂ has slightly higher GWP than C₄F₆, when combined with C₂H₂F₂ it gives even lower normalized CO_{2eq} emissions, which is a significant improvement. This is a surprising result that the combination of the two gasses C₆F₁₂+C₂H₂F₂ gives a great benefit to the etching performance and the CO_{2eq} emissions. In addition, C₆F₁₂+C₂H₂F₂ gives higher SiN etching rate than CAF₆+C₂H₂F₂ which may be beneficial for SiO/SiN etching process such as used in 3DNAND.

### Example 7

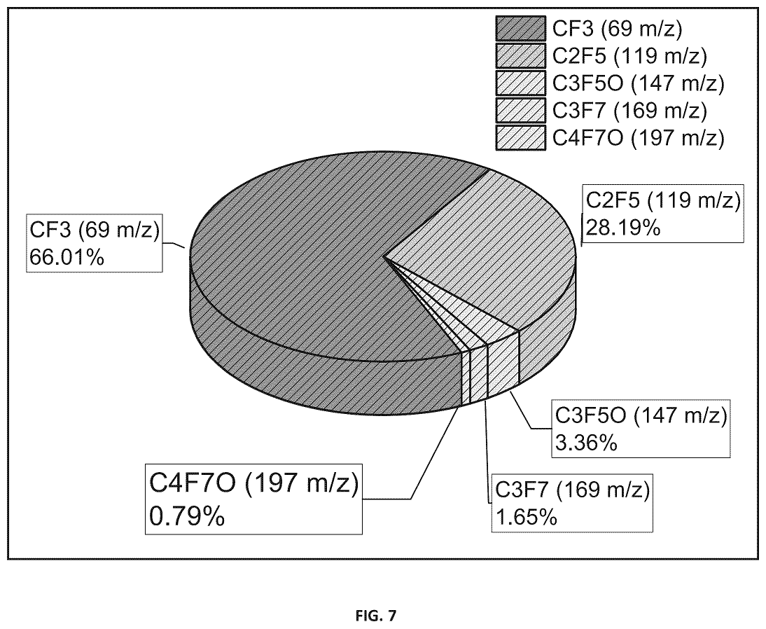

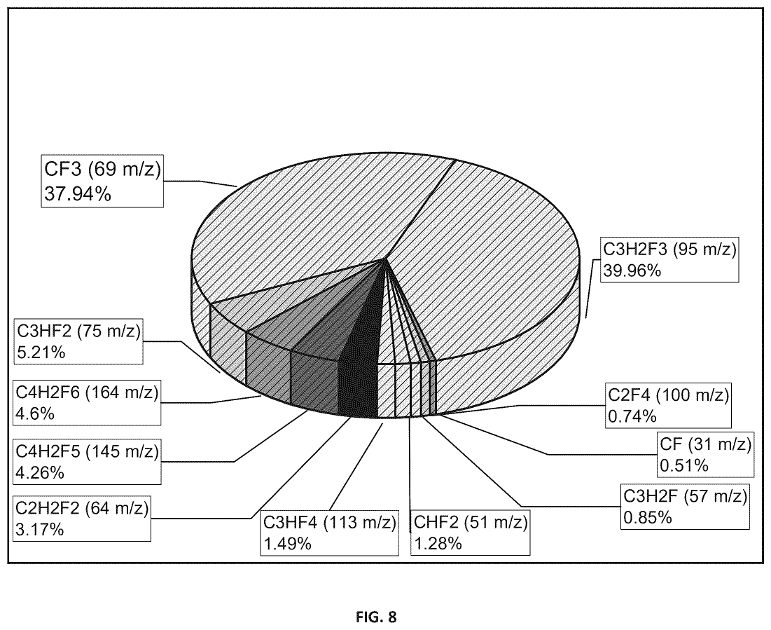

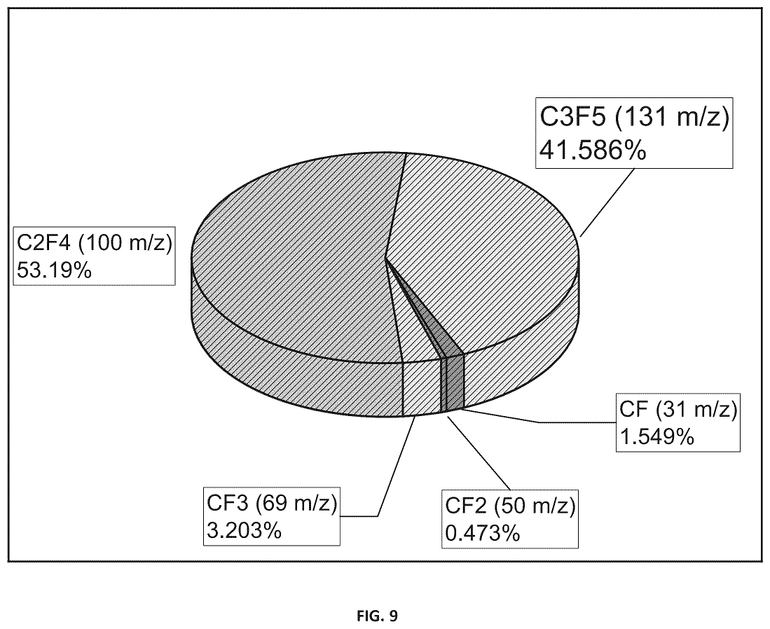

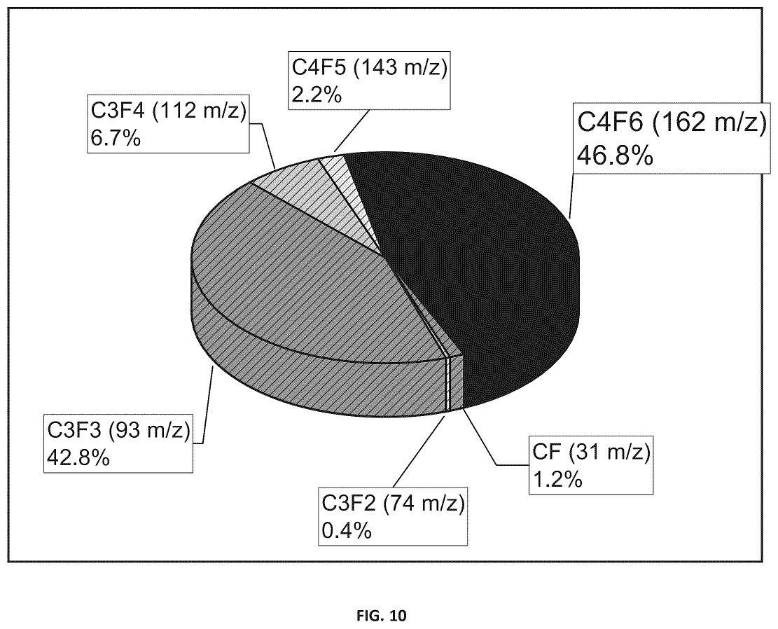

The QMS of C₆F₁₂ was compared to the QMS disclosed in U.S. Pat. No. 9,514,959 of C₄F₈, C₄F₆ and C₄H₂F₆ (CAS #: 382-10-5). The composition of the QMS at an electron volt of 26 eV as a percentage of the total species are shown in FIG. 7 (C₆F ₁₂ CAS #: 2070-70-4), FIG. 8 (C₄H₂F₆), FIG. 9 (C₄F₈) and FIG. 10 (C₄F₆) and the primary species (main species and second species) and are listed below in Table 7. As may be seen from the results both C₆F₁₂ and C₄H₂F₆ make CF₃ as the primary species. However, C₆F₁₂ and C₄F₆ make different species even though both have a double bond and are fully fluorinated molecules. C₆F ₁₂ and C₄F₈ have the same secondary species and are both fully fluorinated molecules. Thus, these QMS of the various recipes may be compared to the emissions and note how even though these molecules have similar species, C₆F₁₂ gives surprising results that were not expected for emitted species and emissions GWP. Etch rates and selectivity may be compared as well and note that even though they have similar QMS species C₆F ₁₂ has surprisingly better etch rate and selectivity as compared to both C₄F₈ and C₄H₂F₆.

TABLE 7

| | QMS | QMS |
|---|---|---|
| | main | second |
| Molecule | species | species |
| C₆F₁₂ | CF₃ | C₃F₅ |
| C₄H₂F₆ | CF₃ | C₃F₃H₂ |
| C₄F₆ | C₃F₃ | CF |
| C₄F₈ | C₂F₄ | C₃F₅ |

### Example 8

The SiO₂ etching rate of C₄F₈, C₆F₁₂, and C₄H₂F₆ were compared under similar conditions as shown below in Table 8 and shown in Table 9 made relative to the C₄F₈ containing process. As can be seen from the results, C₆F₁₂ has a surprising higher etching rate of SiO₂ as compared to C₄H₂F₆ (1.6×) even though both make similar primary ions in the QMS (CF₃). As compared to C₄F₈, C₆F₁₂ also has a much higher etching rate (2.8×) while having the similar secondary ions in the QMS (C₃F₅). Also surprisingly, the CO_{2eq} emissions of the C₆F₁₂ recipe are much lower than either C₄F₈ or C₄H₂F₆. Even though C₄H₂F₆ (GWP 100=4) has a lower GWP than C₆F₁₂ (GWP 100=30) and similar primary QMS species (CF₃), it has higher CO_{2eq} emissions from the plasma etching process as shown in Table 9.

TABLE 8

| | C₄F₈ | C₄H₂F₆ | C₆F₁₂ |
|---|---|---|---|
| Plasma Etch | Recipe | Recipe | Recipe |
| Pressure [mTorr] | 15 | 15 | 15 |
| C₄F₈ FR [sccm] | 20 | 0 | 0 |
| C₄H₂F₆ FR [sccm] | 0 | 0 | 20 |
| C₆F₁₂ FR [sccm] | 0 | 20 | 0 |
| O₂ FR [sccm] | 40 | 40 | 40 |
| Ar FR [sccm] | 150 | 150 | 150 |
| Wafer T [° C.] | 60 | 60 | 60 |

TABLE 9

| | C₄F₈ | C₄H₂F₆ | C₆F₁₂ |
|---|---|---|---|
| | recipe | recipe | recipe |
| Relative SiO₂ Etching Rate | 1.0 | 1.6 | 2.8 |
| Relative CO_{2eq} emissions | 1.0 | 0.4 | 0.2 |

As the results show, the structure of the molecule, the QMS breakdown species, the C/F ratio, and the GWP of the etching molecule are not sufficient to predict both the SiO₂ etching rate as well as the CO_{2eq} emissions of the etching process.

### Example 9

The plasma etching emissions were measured using FTIR from a 300 mm CCP plasma etch tool using the process conditions described below in Table 10 to compare the emissions from C₄H₂F₆+C₄F₆+CH₂F₂, C₄H₂F₆+C₄F₆+C₂H₂F₂, C₆F₁₂+C₄F₆+CH₂F₂, C₆F₁₂+C₄F₆+C₂H₂F₂. These recipes could be used in a high aspect ratio etching application such as SiO₂/SiN alternating layers in 3D NAND. As C₄H₂F₆ and C₆F₁₂ both have similar primary species in the QMS (CF₃) one would expect their CO_{2eq} emissions to be similar. The CO_{2eq} emissions were not normalized SiO₂ etching rate in this example but were made relative to the corresponding CO_{2eq} emissions of the C₄H₂F₆ containing recipe. As may be seen from the results as shown in Table 11, the combination of C₆F₁₂ and CH₂F₂ as compared to C₄H₂F₆ and CH₂F₂ has an 11% lower CO_{2eq} emissions. However, in Table 12 the addition of C₂H₂F₂ to these recipes instead of CH₂F₂ results in a 35% reduction for the C₆F₁₂ recipe as compared to the C₄H₂F₆ recipe. Therefore, it is not obvious that the GWP of the gas alone will predict the CO_{2eq} emissions of the etching process as C₆F₁₂ shows an environmental benefit as compared to C₄H₂F₆ even though it has a higher GWP (30 vs 4), meaning the inherent GWP value of C₆F₁₂=30 while C₄H₂F₆ GWP=4, and when combined with C₂H₂F₂ results in a significant reduction in the CO_{2eq} emissions.

TABLE 10

| | C₄H₂F₆ + | C₄H₂F₆ + | C₆F₁₂ + | C₆F₁₂ + |
|---|---|---|---|---|
| | C₄F₆ + | C₄F₆ + | C₄F₆ + | C₄F₆ + |
| Plasma Etch | CH₂F₂ | C₂H₂F₂ | CH₂F₂ | C₂H₂F₂ |
| Pressure [mTorr] | 22 | 22 | 22 | 22 |
| C₄F₆ FR [sccm] | 17 | 17 | 17 | 17 |
| CH₂F₂ gas [sccm] | 21 | 0 | 21 | 0 |
| C₄H₂F₆ FR [sccm] | 18 | 18 | 0 | 0 |
| C₆F₁₂ FR [sccm] | 0 | 0 | 17 | 17 |
| C₂H₂F₂ FR [sccm] | 0 | 10 | 0 | 10 |
| O₂ FR [sccm] | 33 | 32 | 28 | 28 |
| Ar FR [sccm] | 150 | 150 | 150 | 150 |
| Wafer T [° C.] | 20 | 20 | 20 | 20 |

TABLE 11

| | C₄H₂F₆ + C₄F₆ + CH₂F₂ | C₆F₁₂ + C₄F₆ + CH₂F₂ |
|---|---|---|
| Relative CO_{2eq} | 1.00 | 0.89 |
| emissions | | |

TABLE 12

| | C₄H₂F₆ + C₄F₆ + C₂H₂F₂ | C₆F₁₂ + C₄F₆ + C₂H₂F₂ |
|---|---|---|
| Relative CO_{2eq} | 1.00 | 0.67 |
| emissions | | |

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. An etching method for forming an aperture in a substrate, the method comprising:
exposing the substrate to an etching gas containing a non-cyclic C₆F₁₂;
converting the etching gas to a plasma;
allowing an etching reaction to proceed between the plasma and one or more silicon-containing films containing in the substrate so that the one or more silicon-containing films are selectively etched versus a patterned mask layer deposited on top of the one or more silicon-containing films to form the aperture therein and volatile by-products; and
removing the volatile by-products.

2. The method of claim 1, further comprising adding one or more hydrofluorocarbon or fluorocarbon etching gasses to the etching gas, wherein the one or more hydrofluorocarbon or fluorocarbon etching gasses are selected from C₄F₆, C₄F₈, C₄H₂F₆, CHF₃, CH₂F₂, CH₃F, CF₄, C₂F₆, C₃F₈, SF₆, NF₃, C₂F₄, C₃F₆, C₄F₁₀, C₅F₈, C₆F₆, C₁-C₇ CₓF_{y} molecule (x and y are integers), C₂H₂F₂, C₂H₅F, C₃H₇F, C₃H₂F₆, C₂HF₅, C₁-C₇ CₓF_{y}H_{z} molecule (where x, y and z are integers), or combination thereof.

3. The method of claim 1, further comprising adding C₂H₂F₂ to the etching gas.

4. The method of claim 1, further comprising adding H₂, SF₆, NF₃, NH₃, Cl₂, BCl₃, BF₃, Br₂, F₂, FNO, FNO₃, HBr, HCl, HI, IF₅, IF₇, HF, B₂H₆, or P-containing gases selected from PF₃, PCl₃, PBr₃, PH₃, POCl₃, PF₅, POF₃, PH₃ PCl₅, PBr₅, PF₂BrO, PCl₃₀, PF₂Br, or PR₃ where R is an alkyl, or fluorinated alkyl groups, to the etching gas.

5. The method of claim 1, further comprising adding O₂, CO, CO₂, NO, NO₂, N₂O, SO₂, H₂S, COS, O₃, OF₂, SOF₂, SO₂F₂, CₓO_{y}F_{z}SₘHₙ (where x, y, z, m and n are as integers) selected from (CF₃SO₂)₂O or CF₄SO₂, CₓO_{y}F_{z}NₘHₙ (where x, y, z, m and n are integers) selected from CF₃N═O, or CₓO_{y}F_{z} selected from COF₂, or C₂O₂F₂, CₓO_{y}F_{z}Hₘ (where x, y, z and m are integers) selected from alcohol, ketone, acidic, ester type molecule selected from CF₃OH, CF₃OCF₃, (CF₃) ₂C═O, CF₃COOH or combinations thereof, to the etching gas.

6. The method of claim 1, further comprising adding an inert gas to the etching gas, wherein the inert gas is selected from Ar, Kr, Xe, Ne, N₂, He or combination thereof.

7. The method of claim 1, wherein the non-cyclic C₆F₁₂ is an isomer of C₆F₁₂ with CAS No.: 2070-70-4, 1584-03-8, 755-25-9, 1584-00-5, 360-57-6, 1584-12-7, 3709-71-5, 1584-00-5, 3709-70-4, 359-72-8, 67483-02-7, 67899-37-0, 137202-54-1, 81018-66-8, 87743-93-9, 287101-12-6, 87744-03-4, 71186-98-6, 71186-97-5, 66319-89-9, 58621-70-8, 873536-26-6, or 13429-24-8.

8. The method of claim 1, wherein the non-cyclic C₆F₁₂ is an isomer of C₆F₁₂ with CAS No.: 2070-70-4.

9. The method of claim 1, wherein the non-cyclic C₆F₁₂ is an isomer of C₆F₁₂ with CAS No.: 3709-71-5.

10. The method of claim 1, wherein the temperature of the substrate ranges from approximately −196° C. to approximately 300° C.

11. The method of claim 1, wherein the temperature of the substrate ranges from approximately −196°° C. to approximately 60° C.

12. The method of claim 1, wherein the temperature of the substrate is below approximately −20° C.

13. The method of claim 1, wherein the temperature of the substrate ranges from approximately −196° C. to approximately −50° C.

14. The method of claim 1, wherein after the aperture is formed, the temperature of the substrate is increased to greater than −70° C.

15. The method of claim 1, wherein CO_{2eq} emissions of the volatile by-products are reduced compared to an etching process using etching gases with GWP₁₀₀>30.

16. An etching method for forming an aperture in a substrate, the method comprising:
maintaining the substrate to a temperature ranging from approximately-196° C. to approximately 300° C.;
exposing the substrate to an etching gas containing a non-cyclic C₆F₁₂ (CAS No.: 2070-70-4, or CAS No.: 3709-71-5) into the reaction chamber;
adding C₂H₂F₂ to the etching gas;
converting the etching gas to a plasma;
allowing an etching reaction to proceed between the plasma and one or more silicon-containing films containing in the substrate so that the one or more silicon-containing films are selectively etched versus a patterned mask layer deposited on top of the one or more silicon-containing films to form the aperture therein; and
removing the volatile by-products.

17. The method of claim 16, further comprising adding a phosphorus containing gas and an HF containing gas.

18. The method of claim 16, further comprising adding a fluorocarbon or hydrofluorocarbon gas, an oxidizing gas, and an inert gas.

19. The method of claim 16, wherein CO_{2eq} emissions of the volatile by-products are reduced compared to an etching process using etching gases with GWP₁₀₀>30.

20. An etching method for forming an aperture in a substrate, the method comprising:
maintaining the substrate to a temperature ranging from approximately −196° C. to approximately 300° C.;
exposing the substrate to an etching gas containing a non-cyclic C₆F₁₂ (CAS No.: 2070-70-4) into the reaction chamber;
adding C₂H₂F₂ to the etching gas;
converting the etching gas to a plasma;
allowing an etching reaction to proceed between the plasma and one or more silicon-containing films containing in the substrate so that the one or more silicon-containing films are selectively etched versus a patterned mask layer deposited on top of the one or more silicon-containing films to form the aperture therein; and
removing the volatile by-products.
